(19) United States
(12) Patent Application Publication
(10) Pub. No.: US 2022/0208530 A1
(43) Pub. Date: Jun. 30, 2022

(54) SUBSTRATE PROCESSING APPARATUS, METHOD OF MANUFACTURING SEMICONDUCTOR DEVICE, AND NON-TRANSITORY COMPUTER-READABLE RECORDING MEDIUM

(71) Applicant: KOKUSAI ELECTRIC CORPORATION, Tokyo (JP)

(72) Inventor: Yuji TAKEBAYASHI, Toyama-shi (JP)

(73) Assignee: KOKUSAI ELECTRIC CORPORATION, Tokyo (JP)

(21) Appl. No.: 17/698,725

(22) Filed: Mar. 18, 2022

Related U.S. Application Data
(63) Continuation of application No. PCT/JP2019/038161, filed on Sep. 27, 2019.

(51) Int. Cl. H01J 37/32; H01L 21/687; C23C 16/455; C23C 16/52; C23C 16/44; C23C 16/458

(52) U.S. Cl. CPC H01J 37/32715; H01L 21/68764; H01J 37/32449; H01J 37/32834; H01J 2237/20285; C23C 16/52; C23C 16/4412; C23C 16/4583; H01J 2237/332; C23C 16/45589

(57) ABSTRACT

There is provided technic that includes: a processing chamber having a film formation processing area and a modification processing area adjacent to the film formation processing area; a film former configured to perform film formation processing on a substrate in the film formation processing area; a modifier configured to perform modification processing different from the film formation processing on the substrate in the modification processing area; a substrate mounter configured to support the substrate; and a controller configured to control the substrate mounter such that a speed of moving the substrate is different between the film formation processing area and the modification processing area when the substrate moves in each of the film formation processing area and the modification processing area.

### CROSS-REFERENCE TO RELATED PATENT APPLICATION

This application is a bypass continuation application of PCT International Application No. PCT/JP2019/038161, filed on Sep. 27, 2019, in the W IPO, the entire contents of which are hereby incorporated by reference.

### BACKGROUND

### Field

This present disclosure relates to a substrate processing apparatus, a method of manufacturing a semiconductor device, and a program.

### Description of the Related Art

In general, in a process of manufacturing a semiconductor device, a substrate processing apparatus that performs predetermined process processing on a substrate such as a wafer is used. Examples of the process include film formation processing performed by sequentially supplying a plurality of types of gases. Examples of a substrate processing apparatus that performs such processing include a substrate processing apparatus that performs film formation or the like on a substrate by relatively moving a substrate position and a gas supply position by linear motion of either a cartridge that supplies gas or a substrate mounting table that supports a substrate in a processing container.

### SUMMARY

In a substrate processing apparatus described in related art, a substrate passes below a plurality of cartridges, and processing is performed. In such an apparatus form, the substrate moves at a constant speed. Since rate controlling is performed by the moving speed of the substrate, the number of cartridges corresponding to processing time is required in a case where the processing time varies depending on the type of gas. In this case, the volume of a processing chamber increases, and footprint increases.

This present disclosure provides a configuration capable of suppressing an increase in footprint of a substrate processing apparatus and coping with a plurality of types of processing having different processing times.

One aspect of this present disclosure provides a configuration including: a processing chamber having a film formation processing area and a modification processing area adjacent to the film formation processing area; a film former configured to perform film formation processing on a substrate in the film formation processing area; a modifier configured to perform modification processing different from the film formation processing on the substrate in the modification processing area; a substrate mounter configured to support the substrate; and a controller configured to control the substrate mounter such that a speed of moving the substrate is different between the film formation processing area and the modification processing area when the substrate moves in each of the film formation processing area and the modification processing area.

### BRIEF DESCRIPTION OF THE DRAWINGS

FIGS. 1A to 1C are conceptual diagrams illustrating a schematic configuration example of a substrate processing apparatus used in a first embodiment of this present disclosure, in which

FIG. 1A is a plan view illustrating an A-A cross section. FIG. 1B is a side view illustrating a B-B cross section, and FIG. 1C is a front view illustrating a C-C cross section.

FIG. 2 is an explanatory diagram for explaining a film former used in the first embodiment of this present disclosure.

FIGS. 3A to 3C are explanatory diagrams for explaining a supplier disposed in the film former used in the first embodiment of this present disclosure.

FIG. 4 is an explanatory diagram for explaining an exhauster used in the first embodiment of this present disclosure.

FIGS. 5A and 5B are explanatory diagrams for explaining a supplier disposed in a modifier used in the first embodiment of this present disclosure.

FIG. 6 is a flowchart illustrating a procedure of a substrate processing step in the first embodiment of this present disclosure.

FIG. 7 is an explanatory diagram for explaining a moving path and a speed of a wafer in the substrate processing step in the first embodiment of this present disclosure.

FIG. 8 is an explanatory diagram for explaining a moving path and a speed of a wafer in a substrate processing step in a second embodiment of this present disclosure.

FIG. 9 is a conceptual diagram illustrating a schematic configuration example of a substrate processing apparatus used in a third embodiment of this present disclosure.

FIG. 10 is an explanatory diagram for explaining a moving path and a speed of a wafer in a substrate processing step in the third embodiment of this present disclosure.

FIG. 11 is an explanatory diagram for explaining a moving path and a speed of a wafer in a substrate processing step in a fourth embodiment of this present disclosure.

FIGS. 12A and 12B are conceptual diagrams illustrating a schematic configuration example of a substrate processing apparatus used in a fifth embodiment of this present disclosure.

FIG. 13 is an explanatory diagram for explaining a modifier used in the fifth embodiment of this present disclosure.

FIG. 14 is an explanatory diagram for explaining an auxiliary exhauster used in the fifth embodiment of this present disclosure.

FIG. 15 is an explanatory diagram for explaining a moving path and a speed of a wafer in a substrate processing step in the fifth embodiment of this present disclosure.

### DETAILED DESCRIPTION

Hereinafter, embodiments of this present disclosure will be described with reference to the drawings.

A substrate processing apparatus exemplified in the following description is used in a process of manufacturing a semiconductor device, and is configured to perform predetermined process processing on a substrate to be processed.

The substrate to be processed is, for example, a silicon wafer (hereinafter, simply referred to as a “wafer”) as a semiconductor substrate in which a semiconductor device is built. Note that in the present specification, the term “wafer” may mean “a wafer itself” or “a laminate (assembly) of a wafer and a predetermined layer, film, or the like formed on a surface of the wafer” (that is, a wafer with a predetermined layer, film, or the like formed on a surface of the wafer is referred to as a wafer). In the present specification, the term “surface of a wafer” may mean “a surface (exposed surface) of a wafer itself” or “a surface of a predetermined layer, film, or the like formed on a wafer, that is, an outermost surface of a wafer as a laminate”. In the present specification, the term “substrate” is synonymous with the word “wafer”.

Examples of the predetermined process processing (hereinafter, also simply referred to as “processing”) performed on a wafer include oxidation processing, diffusion processing, annealing processing, etching processing, pre-cleaning processing, chamber cleaning processing, film formation processing, and modification processing. In the present embodiment, in particular, a case where film formation processing and modification processing are performed will be exemplified.

### First Embodiment

First, a first embodiment of this present disclosure will be specifically described.

(1) Configuration of Substrate Processing Apparatus

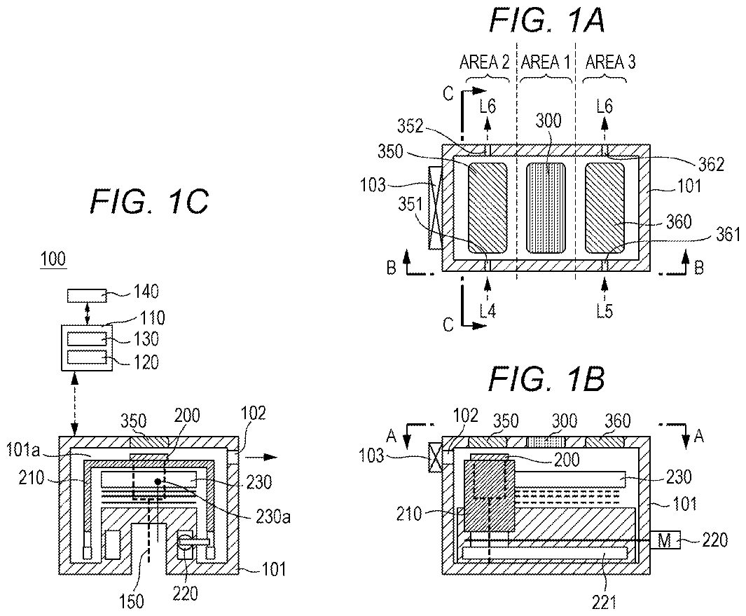

FIGS. 1A to 1C are conceptual diagrams illustrating a schematic configuration example of a substrate processing apparatus used in the first embodiment, in which FIG. 1A is a plan view illustrating an A-A cross section, FIG. 1B is a side view illustrating a B-B cross section, and FIG. 1C is a front view illustrating a C-C cross section.

A substrate processing apparatus 100 includes a processing container 101 for performing processing on a wafer 200. The processing container 101 is configured as a sealed container using a metal material such as aluminum (Al) or stainless steel (SUS). Inside the processing container 101, that is, in a hollow portion, a processing chamber 101a constituting a processing space in which processing is performed on the wafer 200 is formed. On a side wall of the processing container 101, a wafer loading/unloading port 102 is formed and a gate valve 103 that opens and closes the wafer loading/unloading port 102 is disposed, and the wafer 200 can be transferred into and out of the processing container 101 via the wafer loading/unloading port 102.

The processing container 101 has a film formation processing area and a modification processing area in the processing container 101. There may be a plurality of modification processing areas. For example, as illustrated in FIG. 1A, the processing container 101 having a rectangular shape in a plan view is divided into an area 1 (first processing area, also referred to as a film formation processing area) including a film former 300 described later, an area 2 (second processing area, also referred to as first modification processing area) including a modifier 350, and an area 3 (third processing area, also referred to as a second modification processing area) including a modifier 360. The area 2 including the modifier 350 and the area 3 including the modifier 360 are also collectively referred to as a modification processing area. Note that the areas communicate with each other.

Inside the processing container 101, a substrate mounting table 210 as a supporter (supporting table) on which the wafer 200 is mounted and by which the wafer 200 is supported is disposed. The substrate mounting table 210 is formed in a gate shape in a front view as illustrated in FIG. 1C, and is formed in a rectangular shape in a plan view as illustrated in FIG. 1A. The wafer 200 is mounted on and supported by an upper surface (substrate mounting surface) of an upper end of the substrate mounting table 210. A lower end of the substrate mounting table 210 is slidably fixed to a guide rail 221.

As illustrated in FIGS. 1A-1C, a slide mechanism 220 as a driver that reciprocates the substrate mounting table 210 in the processing container 101 is connected to a lower end of the substrate mounting table 210. The slide mechanism 220 is fixed to a bottom of the processing container 101. The slide mechanism 220 can horizontally reciprocate the substrate mounting table 210 and the wafer 200 on the substrate mounting surface between one end side and the other end side in the processing container 101, that is, among the areas 1, 2, and 3. The slide mechanism 220 can be achieved by, for example, a combination of a feed screw (ball screw) and a drive source typified by an electric motor M.

That is, inside the processing container 101, the slide mechanism 220 reciprocates the substrate mounting table 210, and the wafer 200 supported by the substrate mounting table 210 can be thereby reciprocated among the areas 1, 2, and 3.

The slide mechanism 220 performs the reciprocation as described above by operating each drive source such as an electric motor M. Therefore, a relative positional relationship between the wafer 200 mounted on the upper surface of the substrate mounting table 210 and the film former 300, the modifier 350, and the modifier 360 described later can be adjusted by controlling each drive source of the slide mechanism 220.

Below the substrate mounting table 210, a heater 230 is disposed as a heating source for heating the wafer 200. The heater 230 is not reciprocated unlike the substrate mounting table 210, fixed to a bottom of the processing container 101, and is disposed across the area 1 to the area 3.

The degree of energization of the heater 230 is feedback-controlled on the basis of temperature information detected by a temperature sensor 230a disposed near the wafer 200. As a result, the heater 230 is configured to be able to maintain the temperature of the wafer 200 supported by the substrate mounting table 210 at a predetermined temperature.

Note that the substrate mounting table 210 is configured to slide outside the heater 230, and the heater 230 is fixed inside the sliding substrate mounting table 210.

Below the substrate mounting table 210, a wafer lifting mechanism 150 stands by. The wafer lifting mechanism 150 is used when the wafer 200 is loaded and unloaded as described later.

The substrate mounting surface of the substrate mounting table 210 is in direct contact with the wafer 200, and is therefore desirably made of a material such as quartz (SiO₂) or alumina (Al₂O₃). For example, preferably, a susceptor as a support plate made of quartz, alumina, or the like is mounted on the substrate mounting surface of the substrate mounting table 210, and the wafer 200 is mounted on and supported by the susceptor.

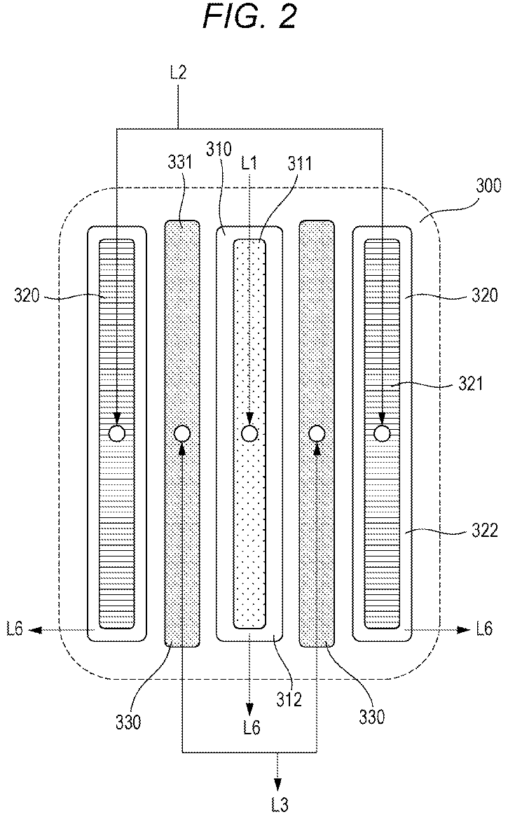

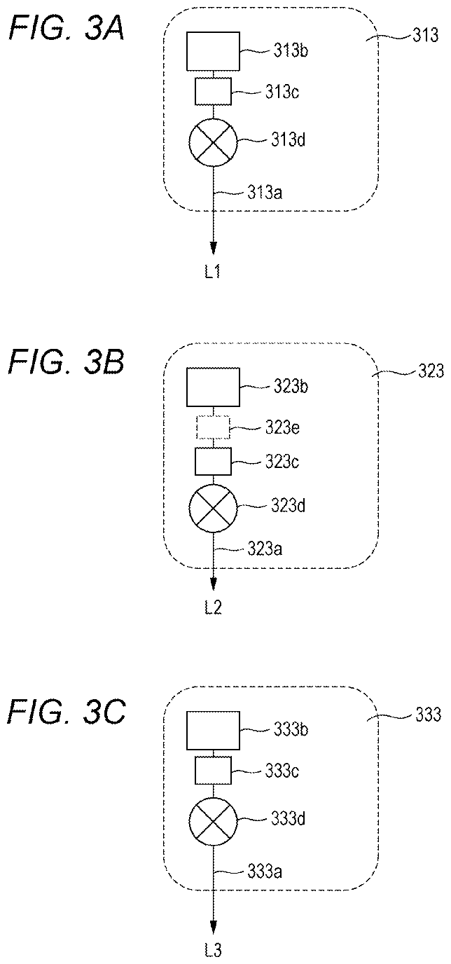

Subsequently, the film former 300 will be described with reference to FIGS. 2 and 3. The film former 300 is used as a gas flow controller that forms a gas flow contactable with the wafer 200 on the substrate mounting table 210. The film former 300 is disposed on a ceiling of the processing chamber 101a. The film former 300 is also referred to as a first processor because the film former 300 performs film formation processing (also referred to as first processing) on a substrate.

The film former 300 includes a raw material gas flow controller 310 that controls a flow of a raw material gas, a reactant gas flow controller 320 that controls a flow of a reactant gas, and an inert gas flow controller 330 that is disposed between the raw material gas flow controller 310 and the reactant gas flow controller 320 and controls a flow of an inert gas.

The reactant gas flow controller 320 is disposed so as to sandwich the raw material gas flow controller 310. That is, the reactant gas flow controller 320, the inert gas flow controller 330, the raw material gas flow controller 310, the inert gas flow controller 330, and the reactant gas flow controller 320 are disposed in this order.

The raw material gas flow controller 310 has a supply structure 311 and an exhaust structure 312. To an upper portion of the supply structure 311, a gas supply pipe 313a of a raw material gas supplier 313 described later is connected, and a lower portion of the supply structure 311 is configured to communicate with the processing chamber 101a. The exhaust structure 312 is disposed on an outer periphery of the supply structure 311. To the exhaust structure 312, an exhauster 340 described later is connected.

Subsequently, the raw material gas supplier 313 will be described with reference to FIG. 3A. FIG. 3A illustrates the raw material gas supplier 313 configured as a part of the raw material gas flow controller. A first gas is mainly supplied from the supply pipe 313a.

The supply pipe 313a includes a first gas supply source 313b, an MFC 313c as a flow rate controller, and a valve 313d as an on-off valve in this order from an upstream side.

A gas (hereinafter, “first gas”) containing a first element is supplied from the supply pipe 313a to the supply structure 311 via the MFC 313c, the valve 313d, and the supply pipe 313a.

The first gas is a raw material gas, that is, one of processing gases. Here, for example, silicon (Si) is used as the first element. In this case, the first gas is a Si gas (also referred to as a Si-containing gas), and is a gas containing Si as a main component. Specifically, a dichlorosilane (DCS, abbreviated as SiH₂Cl₂) gas or hexachlorodisilane (Si₂Cl₆, abbreviated as HCDS) is used. A metal may be used as the first element. In a case where a metal is used as the first element, a gas containing the metal is referred to as a metal-containing gas. In a case where titanium (Ti) is used as a metal, a gas containing the metal is referred to as a Ti-containing gas. For example, as the Ti-containing gas, tetrachlorotitanium (TiCl₄) is used.

In a case where the first gas is liquid at normal temperature and normal pressure, it is only required to dispose a vaporizer (not illustrated) between the first gas supply source 313b and the MFC 313c. Here, description will be made by assuming that the first gas is gas.

Mainly, the supply pipe 313a, the MFC 313c, and the valve 313d constitute the raw material gas supplier 313. Furthermore, the first gas supply source 313b may be included in the raw material gas supplier 313.

The supply structure 311 and the exhaust structure 312 are collectively referred to as the raw material gas flow controller 310. The raw material gas supplier 313 and the exhauster 340 described later may be included in the raw material gas flow controller 310.

The reactant gas flow controller 320 has a supply structure 321 and an exhaust structure 322. To an upper portion of the supply structure 321, a gas supply pipe 323a of a reactant gas supplier 323 described later is connected, and a lower portion of the supply structure 321 is configured to communicate with the processing chamber 101a. The exhaust structure 322 is disposed on an outer periphery of the supply structure 321. To the exhaust structure 322, the exhauster 340 described later is connected.

Subsequently, the reactant gas supplier 323 will be described with reference to FIG. 3B. FIG. 3B illustrates the reactant gas supplier 323 configured as a part of the reactant gas flow controller 320. A second gas is mainly supplied from the supply pipe 323a.

The supply pipe 323a includes a second gas supply source 323b, an MFC 323c as a flow rate controller, and a valve 323d as an on-off valve in this order from an upstream side. In a case where the second gas is used as a plasma state, a plasma generator 323e including a remote plasma unit or the like may be disposed.

A gas (hereinafter, “second gas”) containing a second element is supplied from the supply pipe 323a to the supply structure 321 via the MFC 323c, the valve 323d, and the supply pipe 323a.

The reactant gas is also referred to as the second gas. The second gas is one of processing gases, and is, for example, a nitrogen-containing gas containing nitrogen as a main component. As the nitrogen-containing gas, for example, an ammonia (NH₃) gas is used.

Mainly, the supply pipe 323a, the MFC 323c, the valve 323d, and the gas supply structure 321 constitute the reactant gas supplier 323. Furthermore, the second gas supply source 323b may be included in the reactant gas supplier 323.

The supply structure 321 and the exhaust structure 322 are collectively referred to as the reactant gas flow controller 320. The reactant gas supplier 323 and the exhauster 340 described later may be included in the reactant gas flow controller 320.

The inert gas flow controller 330 has a supply structure 331. To an upper portion of the supply structure 331, a gas supply pipe 333a of an inert gas supplier 333 described later is connected, and a lower portion of the supply structure 331 is configured to communicate with the processing chamber 101a.

Subsequently, the inert gas supplier 333 will be described with reference to FIG. 3C. FIG. 3C illustrates the inert gas supplier 333 configured as a part of the inert gas flow controller 330. Details thereof will be described with reference to FIG. 3C. An inert gas is mainly supplied from the supply pipe 333a.

The supply pipe 333a includes an inert gas supply source 333b, an MFC 333c as a flow rate controller, and a valve 333d as an on-off valve in this order from an upstream side.

An inert gas is supplied from the supply pipe 333a to the supply structure 331 via the MFC 333c, the valve 333d, and the supply pipe 333a.

As the inert gas, for example, a nitrogen (N₂) gas is used.

Mainly, the supply pipe 333a, the MFC 333c, and the valve 333d constitute the inert gas supplier 333. Furthermore, the inert gas supply source 333b may be included in the inert gas supplier 333.

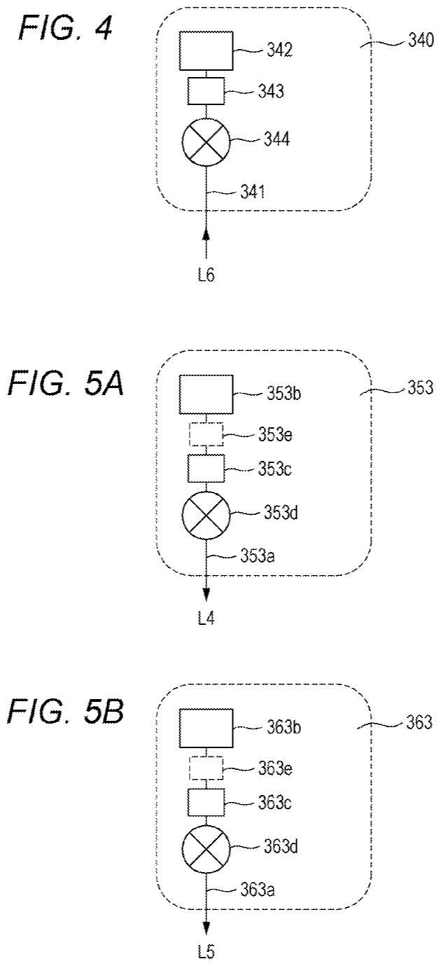

Next, the exhauster 340 will be described with reference to FIG. 4. An exhaust pipe 341 of the exhauster 340 communicates with the exhaust structures 312 and 322. To the exhaust pipe 341, a vacuum pump 342 as a vacuum exhaust device is connected via a valve 344 as an on-off valve and an auto pressure controller (APC) valve 343 as a pressure regulator, which is configured to be able to perform vacuum exhaust such that a pressure in the processing chamber 101a is a predetermined pressure (vacuum degree).

The exhaust pipe 341, the valve 344, and the APC valve 343 are collectively referred to as the first exhauster 340. Note that the vacuum pump 342 may be included in the exhauster 340.

Subsequently, the modifier 350 disposed in the area 2 will be described. The modifier 350 performs processing (also referred to as second processing) different from that of the film former 300, and is also referred to as a second processor. The modifier 350 is disposed in the area 2 adjacent to the area 1. In the area 2, processing different from that in the area 1 is performed. For example, in the area 1, film formation processing in which the film former 300 forms a film on the wafer 200 is performed, and in the area 2, modification processing in which the modifier 350 modifies the film is performed.

In the modification processing, the following processing is performed. For example, plasma processing by direct plasma or remote plasma, or electromagnetic wave supply processing by lamp heating, microwaves, excimer light, hot wire, or the like is performed. Through the processing, a film is subjected to processing such as oxidation, nitridation, or crystallization, impurity removal, residual gas component removal, and the like.

The configuration of the modifier 350 is set according to the type of modification processing. For example, in a case of direct plasma processing, an electrode is disposed in the area 2. In a case of remote plasma processing, a gas supply pipe is connected to the area 2, and a remote plasma unit is disposed in the supply pipe. In a case where lamp heating or excimer light is used, a lamp corresponding to a wavelength thereof is disposed in a processing chamber. In a case of microwaves, a waveguide communicating with a microwave supply source is disposed. In a case where a hot wire is used, a hot wire structure is disposed in a processing chamber, a gas supply pipe, or the like.

In a case where gas is required for modification, a structure capable of supplying gas to the area 2 is disposed. For example, as illustrated in FIG. 1A, a supply hole 351 is formed in the area 2. Furthermore, an exhaust port 352 is formed in the area 2. The supply hole 351 is configured to communicate with the supply pipe 353a of the modification gas supply line 353 illustrated in FIG. 5. The exhaust port 352 is configured to be connected to the exhauster 340.

Subsequently, the modification gas supply line 353 will be described with reference to FIG. 5A. FIG. 5A illustrates the modification gas supply line 353 configured as a part of the modifier 350. A modification gas is mainly supplied from the supply pipe 353a.

The supply pipe 353a includes a modification gas supply source 353b, an MFC 353c as a flow rate controller, and a valve 353d as an on-off valve in this order from an upstream side.

A modification gas is supplied to the area 2 via the MFC 353c, the valve 353d, and the supply pipe 353a.

As the modification gas, any gas that contributes to modification of a film formed in the area 1 can be used, and for example, a gas containing nitrogen, oxygen, hydrogen, fluorine, or the like is used. Hereinafter, the type of gas and an example of use in the modification processing will be described. A nitrogen-containing gas containing nitrogen is used for nitridation processing for nitriding a film or simply for heating processing. In a case of the nitridation processing, as the nitrogen-containing gas, for example, an ammonia (NH₃) gas is used. In a case of the heating processing, as the nitrogen-containing gas, a nitrogen (Na) gas is used. In a case of an oxygen-containing gas containing oxygen, as the oxygen-containing gas used in oxidation processing for oxidizing a film, for example, an oxygen (O₂) gas, a nitrogen monoxide (NO) gas, or an ozone (O₁) gas is used. In a case where a substance in a film is subjected to reduction processing or hydrogen termination processing, a hydrogen-containing gas is used. For example, a water (H₂O) gas or a hydrogen peroxide (H₂O₂) gas is used. In a case where fluorine termination processing is performed, a fluorine trichloride (ClF₃) gas, a fluorine (F₂) gas, a nitrogen trifluoride (NF₃) gas, a carbon tetralluoride (CF₄) gas, or the like is used.

In a case where it is desired to bring a modification gas into a plasma state before the modification gas is supplied to the processing chamber 101a, a remote plasma unit 353e may be used.

Mainly, the supply pipe 353a, the MFC 353c, and the valve 353d constitute the modification gas supply line 353. Furthermore, the modification gas supply source 353b and the remote plasma unit 353e may be included in the modification gas supply line 353.

Subsequently, the modifier 360 disposed in the area 3 will be described. The modifier 360 is disposed in the area 3. In the area 3, processing different from that in the area 1 is performed. For example, in the area 1, film formation processing in which the film former 300 forms a film on the wafer 200 is performed, and in the area 3, modification processing in which the modifier 360 modifies the film is performed.

Note that the modification processing in the area 3 can be appropriately changed by substrate processing, and may be modification processing similar to that in the area 2 or may be modification processing different from that in the area 2.

Similar to the modifier 350, the configuration of the modifier 360 is set according to the type of modification processing. When the film is further heated, a heating lamp may be used as the modifier 360. In a case where plasma processing is performed, an electrode may be used as a plasma generator.

In a case where gas is required for modification processing, a structure capable of supplying a modification gas to the area 3 is disposed. For example, as illustrated in FIG. 1A, a supply hole 361 is formed in the area 3. Furthermore, an exhaust port 362 is formed in the area 3. The supply hole 361 is configured to communicate with the supply pipe 363a of the modification gas supply line 363 illustrated in FIG. 5. The exhaust port 362 is configured to be connected to the exhauster 340.

Subsequently, the modification gas supply line 363 will be described with reference to FIG. 5. FIG. 5B illustrates the modification gas supply line 363 configured as a part of the modifier 360. A modification gas is mainly supplied from the supply pipe 363a.

The supply pipe 363a includes a modification gas supply source 363b, an MFC 363c as a flow rate controller, and a valve 363d as an on-off valve in this order from an upstream side.

A modification gas is supplied to the area 3 via the MFC 363c, the valve 363d, and the supply pipe 363a.

Similar to the area 2, as the modification gas, any gas that contributes to modification of a film formed in the area 1 can be used, and for example, a gas containing nitrogen, oxygen, hydrogen, fluorine, or the like is used.

Mainly, the supply pipe 363a, the MFC 363c, and the valve 363d constitute the modification gas supply line 363. Furthermore, the modification gas supply source 363b may be included in the modification gas supply line 363.

In a case where it is desired to bring a modification gas into a plasma state before the modification gas is supplied to the processing chamber 101a, a remote plasma unit 363e may be used.

Mainly, the supply pipe 363a, the MFC 363c, and the valve 363d constitute the modification gas supply line 363. Furthermore, the modification gas supply source 363b and the remote plasma unit 363e may be included in the modification gas supply line 363.

(Controller)

As illustrated in FIG. 1, the substrate processing apparatus 100 includes a controller 110 as a controller that controls operation of each unit of the substrate processing apparatus 100. The controller 110 is configured as a computer device including at least hardware resources such as a calculator 120 and a memory 130. The controller 110 is connected to each of the above-described configurations, and is configured to read a control program and a process recipe (hereinafter, these are collectively and simply referred to as “a program”), which are predetermined software, from the memory 130 according to an instruction from a host controller, an operator, or the like, and to control operation of each of the configurations according to the contents thereof. That is, the controller 110 is configured such that a hardware resource executes a program that is predetermined software, and the hardware resource and the predetermined software thereby cooperate to control operation of each unit of the substrate processing apparatus 100. Note that in the present specification, the term “program” may include only the control program alone, only the process recipe alone, or both.

The controller 110 as described above may be configured as a dedicated computer, or may be configured as a general-purpose computer. For example, the controller 110 in the present embodiment can be configured by preparing an external memory device 140 storing the above-described program and installing the program in a general-purpose computer using the external memory device 140. Note that the external memory device 140 includes, for example, a magnetic tape, a magnetic disk such as a flexible disk or a hard disk, an optical disk such as a CD or a DVD, a magneto-optical disk such as an MO, and a semiconductor memory such as a USB memory or a memory card. The means for supplying the program to the computer is not limited to the supply via the external memory device 140. For example, a communication means such as the Internet or a dedicated line may be used, or the program may be supplied without going through the external memory device 140 by receiving information from a host device via a receiver.

The memory 130 in the controller 110 and the external memory device 140 connectable to the controller 110 are configured as non-transitory computer-readable recording media. Hereinafter, these are also collectively and simply referred to as a recording medium. Note that in the present specification, the term “recording medium” may include only the memory 130 alone, which is a memory device, only the external memory device 140 alone, or both.

(2) Outline of Substrate Processing Step

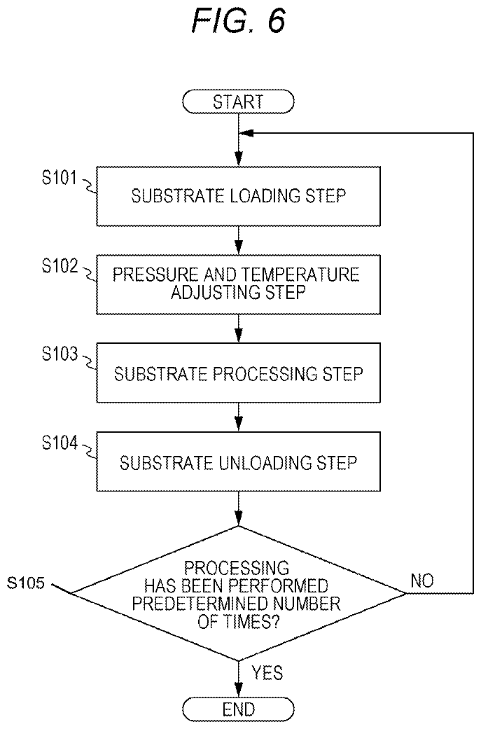

Next, with reference to FIG. 6, a step of forming a thin film on the wafer 200 using the substrate processing apparatus 100 will be described as one step of a process of manufacturing a semiconductor device. Note that in the following description, operation of each of the units constituting the substrate processing apparatus 100 is controlled by the controller 110.

In the present embodiment, the following will be described as an example. An HCDS gas is supplied as a raw material gas from the raw material gas supplier 313. A N₂ gas is supplied as an inert gas from the inert gas supplier 333. An NH₃ gas is supplied as a modification gas from the modification gas supply lines 353 and 363. In the modification gas supply lines, the NH₃ gas is brought into a plasma state using the remote plasma units 353e and 363e, respectively. Note that in the present embodiment, the reactant gas supplier 323 is not used.

(Substrate Loading Step: S101)

A substrate loading step S101 will be described.

In the substrate processing step, first, the wafer 200 is loaded into the processing container 101. Specifically, the gate valve 103 disposed in the substrate loading/unloading port 102 formed on a side surface of the processing container 101 of the substrate processing apparatus 100 is opened, and the wafer 200 is loaded into the processing container 101 using a wafer transfer machine (not illustrated). Thereafter, the wafer 200 loaded into the processing container 101 is mounted on a substrate mounting surface of the substrate mounting table 210 using the wafer lifting mechanism 150 including a lift pin or the like. Then, the wafer transfer machine is retracted to the outside of the processing container 101, the gate valve 103 is closed to close the substrate loading/unloading port 102, and the inside of the processing container 101 is scaled.

(Pressure and Temperature Adjusting Step: S102)

A pressure and temperature adjusting step S102 will be described.

After the wafer 200 is loaded into the processing container 101 and mounted on the substrate mounting surface of the substrate mounting table 210, the pressure and temperature in the processing container 101 are adjusted. At this time, the heater 230 is controlled on the basis of a value detected by the temperature sensor 230a such that the wafer 200 has a desired processing temperature, for example, a predetermined temperature within a range of 300 to 600° C. The wafer 200 is continuously heated at least until processing on the wafer 200 is completed.

(Substrate Processing Step: S103)

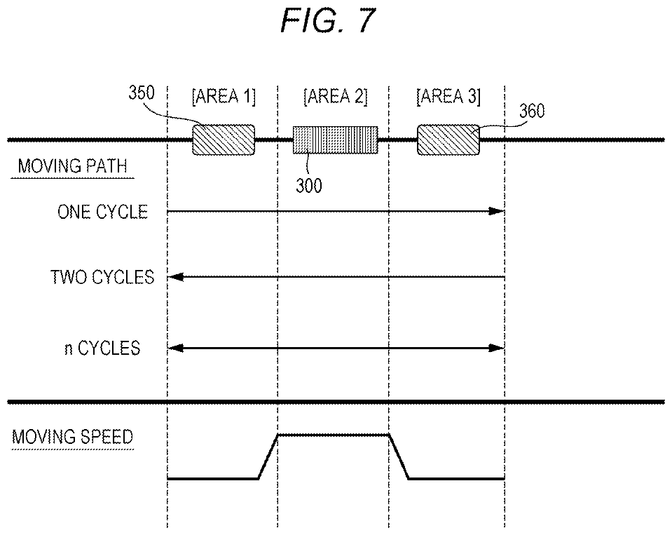

A substrate processing step S103 will be described. A moving path and a moving speed of the wafer 200 in the substrate processing step S103 will be described with reference to FIG. 7. FIG. 7 is a diagram for explaining a relationship between the moving path and the moving speed of the wafer 200. In the description of the moving speed in FIG. 7, the speed increases as it goes upward in the graph, and the speed decreases as it goes downward in the graph.

After the inside of the processing container 101 reaches a desired processing pressure and the wafer 200 reaches a desired processing temperature, the substrate processing step S103 is performed.

First, a processing gas is supplied in each of the areas 1, 2, and 3. Specifically, in the area 1, an HCDS gas is supplied from the raw material gas supplier 313, and a N₂ gas is supplied from the inert gas supplier 333. The N₂ gas serves as a gas shield such that the HCDS gas does not diffuse into the areas 2 and 3, that is, the HCDS gas is spatially separated from the other areas.

In the area 2, an NH₃ gas in a plasma state is supplied from the modification gas supply line 353. Similarly, in the area 3, an NH₃ gas in a plasma state is supplied from the modification gas supply line 363.

in parallel with the gas supply to each of the areas, the exhauster 340 is operated to control the processing chamber 101a to be maintained at a desired pressure.

When the state of the space separation is stabilized in the area 1, as illustrated in FIG. 7, the substrate mounter 210 on which the wafer 200 is mounted is reciprocated among the areas 1, 2, and 3.

The wafer 200 is processed for several cycles with the area 2→the area 1→the area 3 as one cycle. In the area 1, the HCDS supplied onto the wafer 200 is decomposed to form a Si-containing layer. In the areas 2 and 3, NH₃ in a plasma state is supplied to the Si-containing layer, and a Si component and a N component of the Si-containing layer are bonded to each other to form a SiN layer in which Si and N are bonded to each other.

The following description focuses only on the raw material gas and the reactant gas, and focuses on a reciprocating path (two cycles) to clarify a low. A surface of the wafer 200 is exposed to various gases in the following order, and a desired film is formed by repeating the exposure.

HCDS (area 1)→NH₃ (area 3)→HCDS (area 1)→NH₃ (area 2)

In the area 1, a Si-containing layer containing a component of the HCDS gas supplied from the supply hole 311 is formed on the wafer 200. In the next area 3, NH₃ plasma is supplied to the Si-containing layer formed in the area 1 to modify the Si-containing layer, thereby forming a SiN layer. In the next area 1, a Si-containing layer is formed in the SiN layer modified in the area 3. In the next area 2. NH₃ plasma is supplied to the Si-containing layer formed in the area 1 to modify the Si-containing layer, thereby forming a SiN layer. By reciprocating the substrate mounting table 210 in this manner, the above-described processing is performed on the wafer 200 to form a desired film.

Examples of processing conditions in the substrate processing step S103 include the following. Processing temperature: 300 to 600° C., preferably 450 to 550° C.

Processing pressure: 10 to 5000 Pa, preferably 50 to 1000 Pa

HCDS gas supply flow rate: 0.01 to 5 slim, preferably 0.1 to 1 slm

NH₃ gas supply flow rate (each line): 0.1 to 20 slm, preferably 0.1 to 1 slm

N₂ gas supply flow rate (each line): 0.1 to 20 slm, preferably 1 to 10 slm

Time per cycle (one side passage): 2 to 10 seconds

After a SiN film having a predetermined composition and a predetermined film thickness is formed on the wafer 200, a N₂ gas as a purge gas is supplied from the inert gas supplier 333 into the processing container 101, and is exhausted from the exhauster 340 via the exhaust structure 312 and the exhaust holes 352 and 362. As a result, the inside of the processing container 101 is purged, and a gas remaining in the processing container 101, a reaction by-product, and the like are removed from the inside of the processing container 101. Thereafter, the atmosphere in the processing container 101 is replaced with an inert gas (inert gas replacement), and the pressure in the processing container 101 is changed to a predetermined transfer pressure or returned to a normal pressure (return to atmospheric pressure).

It is generally known that time for modification is longer than time for forming a layer on a wafer. In the present embodiment, the processing time in the area 2 or 3 is longer than that in the area 1. In this case, when the wafer is moved at a constant speed as in related art, it is necessary to increase the areas of the areas 2 and 3 in which the modification processing is performed, which increases footprint of the processing apparatus.

Therefore, in this present disclosure, as described in FIG. 7, the moving speed of the wafer 200 is reduced to increase the processing time in the modification processing area. Specifically, the slide mechanism 220 performs control to move the substrate mounting table 210 (wafer 200) at a first speed which is a predetermined speed in the area 1, and to move the substrate mounting table 210 (wafer 200) at a second speed lower than the predetermined speed in the area 2. The same applies to the area 3.

By varying the moving speed of the substrate mounting table 210 depending on the processing contents in each of the areas in this manner, a configuration capable of suppressing an increase in footprint of the processing apparatus 100 and coping with a plurality of types of processing having different processing times is achieved.

(Substrate Unloading Step: S104)

Subsequently, a substrate unloading step S104 will be described. When a desired film is formed in the substrate processing step S103, the substrate unloading step (S104) is performed. In the substrate unloading step (S104), the processed wafer 200 is unloaded out of the processing container 101 using a wafer transfer machine in a reverse procedure to the substrate loading step (S101).

(Processing Performance Step: S105)

Subsequently, a determination of the number of processing performances in step S105 will be described. It is determined if the series of processing from the substrate loading step (S101) to the substrate unloading step (S104) described above is performed on each of the wafers 200 to be processed. That is, the series of processing (S101 to S104) described above is performed a predetermined number of times by replacing the wafer 200. The predetermined number of times is at least the number of each of the wafers 200 to be processed. When the predetermined number of processing is not reached, the process returns to step S101 and completed the series of processing (S101 to S104) until the predetermined number is reached. When the processing on all the wafers 200 to be processed is completed, the substrate processing step ends.

According to the present embodiment, a moving range in the area having the modifier can be reduced as compared with a case of performing a linear motion. Therefore, the volume of the processing container 101 can be reduced, and this makes it possible to reduce footprint of the substrate processing apparatus 100. As a result, productivity per unit area of the substrate processing apparatus 100 can be improved.

### Second Embodiment

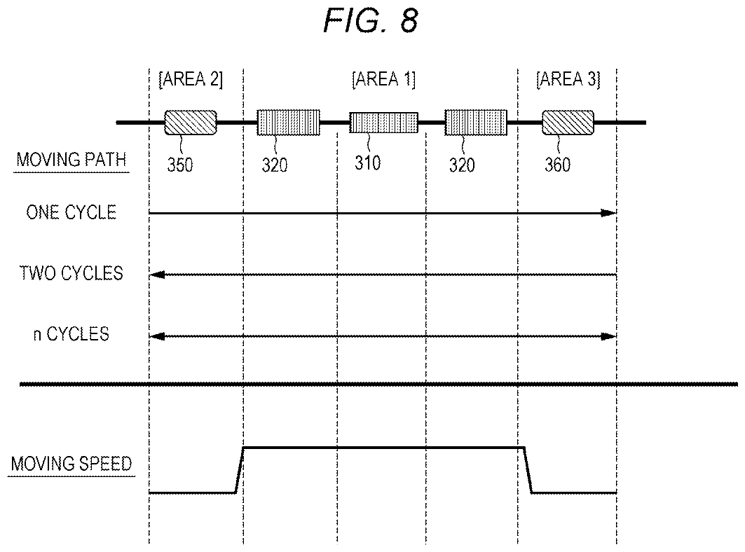

Next, with reference to FIG. 8, a second embodiment of this present disclosure will be described. Here, a difference from the above-described first embodiment will be mainly described, and description of other points will be omitted.

In the second embodiment, the substrate processing step S103 is different from that of the first embodiment. The other configurations are similar to those of the first embodiment. In FIG. 8, the wafer 200 is processed also using the reactant gas flow controller 320. In the present embodiment, specific contents of the substrate processing step S103 will be described below.

In the area 1, an HCDS gas is supplied from the raw material gas supplier 313, an NH₃ gas is supplied from the reactant gas supplier 323, and a N₂ gas is supplied from the inert gas supplier 333. The N₂ gas serves as a gas shield so as to prevent generation of a by-product due to contact of the HCDS gas with the NH; gas. This spatially separates the HCDS gas and the NH₃ gas from each other.

In the area 2, an NH₃ gas in a plasma state is supplied from the modification gas supply line 353. Similarly, in the area 3, an NH₃ gas in a plasma state is supplied from the modification gas supply line 363.

In parallel with the gas supply to each of the areas, the exhauster 340 is operated to control the processing chamber 101a to be maintained at a desired pressure.

When the state of the space separation is stabilized in the area 1, as illustrated in FIG. 8, the substrate mounter 210 on which the wafer 200 is mounted is reciprocated among the areas 1, 2, and 3.

The wafer 200 is processed for several cycles with the area 2→the area 1→the area 3 as one cycle. Below the raw material gas flow controller 310 in the area 1, the HCDS supplied onto the wafer 200 is decomposed to form a Si-containing layer. The Si-containing layer contains a component other than Si, for example, Cl.

Thereafter, an NH₃ gas is supplied to try to bond a Si component and a N component to each other. However, ammonium chloride (NH₄Cl), which is a Cl-based by-product generated at the time of bonding, serves as a reaction inhibitor, and a SiN film in which impurities remain is obtained. Therefore, a low-quality film is formed, or a film having variations in quality in a wafer plane is formed.

Therefore, in this step, a non-plasma NH₃ gas is supplied from the reactant gas flow controller 320 to remove a Cl-based by-product generated during an initial reaction, and then nitridation processing is performed by the modifier 360 to form a high-quality SiN film with less impurities.

The following description focuses only on the raw material gas and the reactant gas, and focuses on a reciprocating path. A surface of the wafer 200 is exposed to various gases in the following order, and a desired film is formed. Note that here, the plasma in ( ) represents a gas in a plasma state, and the non-plasma in ( ) represents a gas in a non-plasma state.

HCDS (area 1)→NH₃ (non-plasma, area 1)→NH₃ (plasma, area 3)→NH₃ (non-plasma, area 1)→HCDS (area 1)→NH₃ (non-plasma, area 1)→NH₃ (plasma, area 2)

In the area 1, a silicon-containing layer containing a component of the HCDS gas supplied from the supply hole 311, specifically, containing Si and Cl, is formed on the wafer 200. Furthermore, an NH₃ gas in a non-plasma state is supplied to the silicon-containing layer to remove a Cl-based by-product. In the area 3, a N component is supplied to a portion from which Cl has been desorbed, and a SiN layer with less impurities is formed. In the next area 1, a silicon-containing layer containing Si and Cl is formed on the SiN layer formed in the area 3, and an NH₃ gas in a non-plasma state is further supplied to the silicon-containing layer to remove a Cl-based by-product. In the area 2, a N component is supplied to a portion from which Cl has been desorbed, and a SiN layer with less impurities is formed. By reciprocating the substrate mounting table 210 in this manner, the above-described processing is performed on the wafer 200 to form a high-quality film with less impurities.

Furthermore, in this present disclosure, as described in FIG. 8, the moving speed of the wafer 200 is reduced to increase the processing time in the modification processing area. Specifically, the slide mechanism 220 performs control to move the substrate mounting table 210 at a first speed which is a predetermined speed in the area 1, and to move the substrate mounting table 210 at a third speed lower than the predetermined speed in the area 2. The same applies to the area 3.

Furthermore, in the areas 2 and 3, the movement of the substrate mounting table 210 may be stopped to perform modification processing. By stopping the movement of the substrate mounting table 210 and performing plasma processing, a nitrogen component can be reliably fed to an empty adsorption site in the Si-containing layer. Therefore, a high-quality film with less impurities can be formed more reliably.

Note that the present embodiment is also advantageous in the following points. When the wafer 200 passes below the reactant gas flow controller 320, for example, an adsorption site is filled with HCl generated at the time of NH₃ exposure on a surface of the wafer, and the above-described reaction may be difficult to proceed. However, even in this case, according to the present embodiment, as described above, the surface of the wafer 200 is continuously exposed to NH₃ twice, and the nitridation processing is continuously performed twice. Therefore, HCl filling the adsorption site at the time of the second NH₃ exposure can be removed. As a result, the adsorption site can be optimized for each cycle, and the above-described reaction can appropriately proceed. In addition, Cl may remain in a TiN layer formed on the surface of the wafer 200. However, even in this case, as described above, the residual CI in the TiN layer can be sufficiently removed by the nitridation processing continuously performed twice. This makes it possible to form a TiN layer having an extremely low Cl concentration.

### Third Embodiment

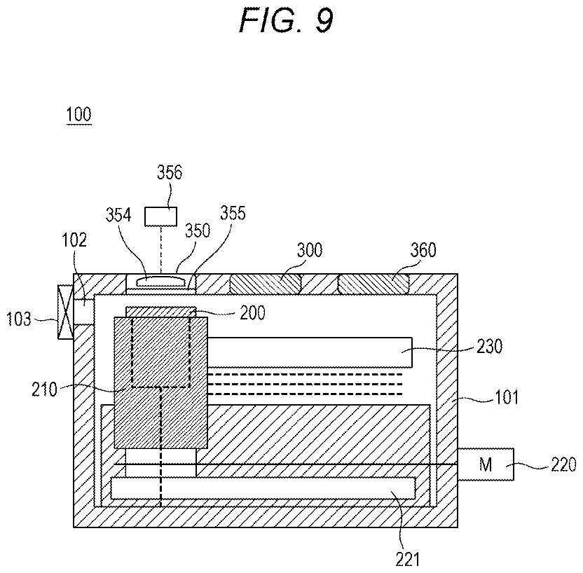

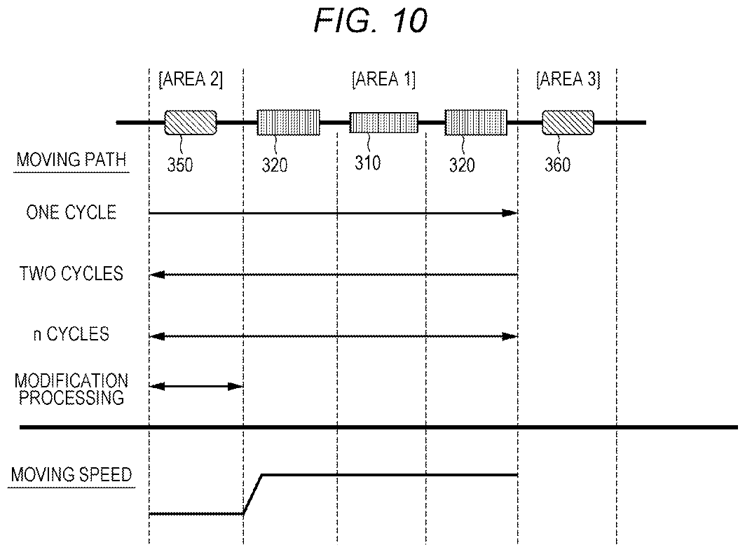

Next, with reference to FIGS. 9 and 10, a third embodiment of this present disclosure will be described. Here, a difference from the above-described first embodiment will be mainly described, and description of other points will be omitted.

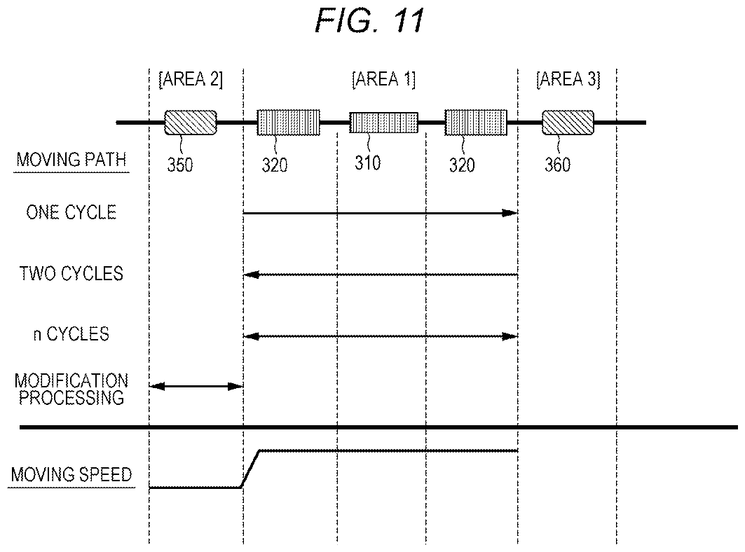

FIG. 9 is a diagram corresponding to FIG. 1B. The configuration of the modifier 350 is different from that of FIG. 11B. Here, a lamp 354 is used as one configuration of the modifier 350. The lamp 354 supplies an electromagnetic wave into the area 2 through a window 355. The lamp 354 is controlled by a lamp controller 356. The modifier 350 includes the lamp 354 and the lamp controller 356.

In addition, the third embodiment is different from the first embodiment in a modification method in the substrate processing step S103. Note that in the present embodiment, the area 3 is not used.

As illustrated in FIG. 10, in the area 1, a raw material gas and a reactant gas are alternately supplied to form a desired film. For example, an HCDS gas is used as the raw material gas, and an NH₃ gas is used as the reactant gas.

The wafer 200 is processed for several cycles with the area 1→the area 2 as one cycle. The following description focuses only on the raw material gas, the reactant gas, and lamp heating, and focuses on a reciprocating path. A surface of the wafer 200 is exposed to various gases in the following order. A desired SiN layer formed in the area 1 is subjected to, for example, lamp heating in the area 2. By heating, the degree of bonding of components in the layer can be increased.

HCDS (area 1)→NH₃ (area 1)→HCDS (area 1)→NH₃ (area 1)→lamp heating (area 2)

Although the SiN layer is formed in the area 1, impurities are mixed in the SiN layer as in the second embodiment. Therefore, in the present embodiment, the impurities are desorbed by performing lamp heating in the area 2.

In addition, in this present disclosure, as described in FIG. 10, the moving speed of the wafer 200 is reduced to increase the processing time in each of the areas. Specifically, the slide mechanism 220 performs control to move the substrate mounting table 210 at a first speed which is a predetermined speed in the area 1, and to move the substrate mounting table 210 at a fourth speed lower than the predetermined speed in the area 2.

At the time of heating with a lamp, by reducing the moving speed of the substrate mounting table 210, lamp irradiation time is increased, and impurities can be desorbed more reliably.

By varying the moving speed of the substrate mounting table 210 depending on the processing contents in each of the areas in this manner, a configuration capable of suppressing an increase in footprint of the processing apparatus 100 and coping with a plurality of types of processing having different processing times is achieved.

### Fourth Embodiment

Next, with reference to FIG. 11, a fourth embodiment of this present disclosure will be described. Here, a difference from the above-described third embodiment will be mainly described, and description of other points will be omitted.

In the fourth embodiment, the lamp structure illustrated in FIG. 9 is used as the modifier 350 as in the third embodiment. In addition, the fourth embodiment is different from the third embodiment in a film forming method in the area 1 in the substrate processing step S103.

The substrate processing step S103 will be described with reference to FIG. 11. In the area 1, a raw material gas and a reactant gas are simultaneously supplied to the area 1 to cause a gas phase reaction, thereby forming a desired film. Here, an HCDS gas is used as the raw material gas, and an NH₃ gas is used as the reactant gas. The substrate mounting table 210 is reciprocated in the area 1 to form a desired film on the wafer 200. The formed film contains impurities as in the third embodiment. Therefore, after a desired film is formed, lamp processing is performed in the area 2 to desorb impurities.

The following description focuses only on the raw material gas, the reactant gas, and lamp heating, and focuses on a reciprocating path. A surface of the wafer 200 is exposed to various gases in the following order. A desired SiN layer formed in the area 1 is subjected to lamp heating in the area 3 to desorb impurities.

Simultaneous supply of NH₃ and HCDS (reciprocation in area 1)→lamp heating (area 2)

Note that in this step, since a film is formed using a gas phase reaction, a film having a high degree of bonding is not formed unlike the third embodiment. Therefore, even if a film having a desired thickness is formed and then subjected to lamp heating, impurities can be desorbed from the film. Since it is not necessary to perform the lamp processing in the area 2 each time unlike the third embodiment, a desired film can be formed in a shorter time than in the third embodiment.

In addition, at the time of heating with a lamp, by reducing the moving speed of the substrate mounting table 210, lamp irradiation time is increased, and impurities can be thereby desorbed more reliably.

By varying the moving speed of the substrate mounting table 210 depending on the processing contents in each of the areas in this manner, a configuration capable of suppressing an increase in footprint of the processing apparatus 100 and coping with a plurality of types of processing having different processing times is achieved.

Note that in the third and fourth embodiments, the lamp is disposed only in the area 2, but this present disclosure is not limited thereto, and the lamp may be disposed in the area 3 instead of the area 2, or may be disposed in both the areas 2 and 3.

In addition, in the third and fourth embodiments, the description has been made using the heating lamp, but this present disclosure is not limited thereto, and an ultraviolet lamp may be used depending on processing contents. In this case, for example, by irradiation with an ultraviolet lamp, the bonding in the layer may be cut to reduce stencil.

### Fifth Embodiment

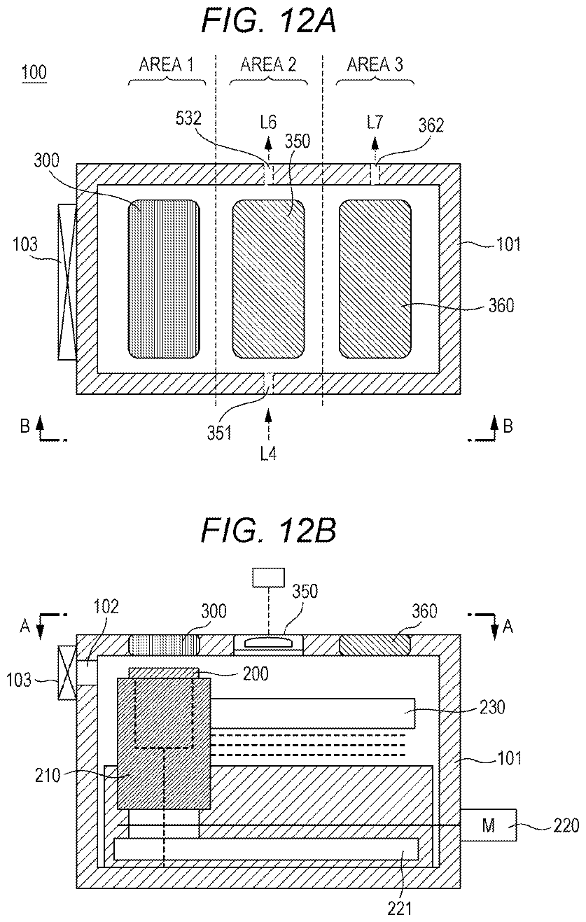

Next, with reference to FIGS. 12 to 15, a fifth embodiment of this present disclosure will be described. Here, a difference from the above-described first embodiment will be mainly described, and description of other points will be omitted.

The fifth embodiment is different from the first embodiment in the location of the second area including the modifier 350, the configuration of the modifier 360, and the substrate processing step S103. In addition, in the present embodiment, an example of processing the wafer 200 having a deep groove will be described.

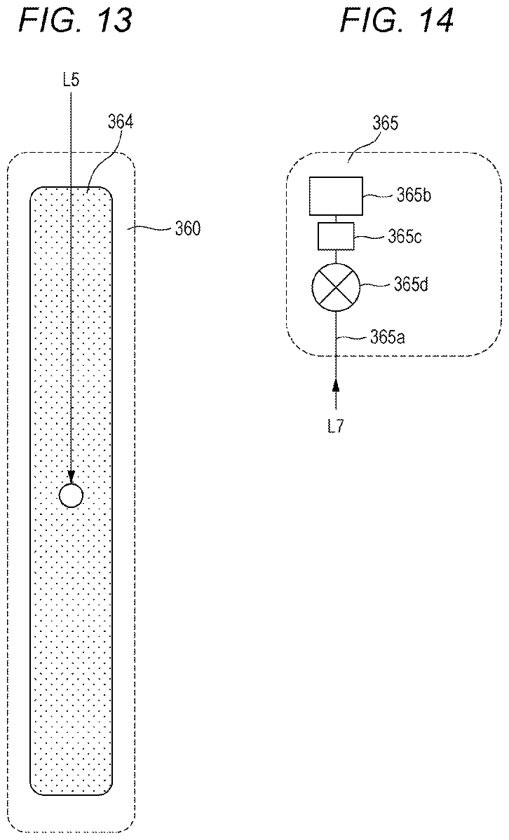

First, with reference to FIGS. 12 to 14, a substrate processing apparatus according to the present embodiment will be described, focusing on the differences. FIG. 12A is a diagram corresponding to FIG. 1A. FIG. 12B is a diagram corresponding to FIG. 1B. FIG. 13 is a diagram for explaining a gas supply structure 364 which is one configuration of the modifier 360. FIG. 14 is a diagram for explaining an exhauster 365 which is one configuration of the modifier 360.

In the first embodiment, the areas 2 and 3 are provided on both sides of the area 1. However, in the present embodiment, the area 1 is adjacent to the substrate loading/unloading port 102, and the area 2 is adjacent to the opposite side to the substrate loading/unloading port 102. Furthermore, the area 3 is provided on the opposite side to the area 1 when viewed from the area 2. That is, the areas 1, 2, and 3 are provided in this order as viewed from the substrate loading/unloading port 102.

In the area 2, the modifier 350 having a lamp structure similar to that of the third embodiment is used. In the area 3, the modifier 360 that enhances purge is used. The modifier 360 includes the supply structure 364 disposed on a ceiling of the processing chamber 101a and the exhauster 365 communicating with the exhaust hole 362.

As illustrated in FIG. 13, the supply structure 364 is configured to communicate with the modification gas supply line 363. From the modification gas supply line 363, a purge gas for exhausting a reaction excess gas, a by-product, and the like is supplied. As the purge gas, for example, a N₂ gas is used. The supply structure 364 is disposed on a ceiling of the processing chamber 101a, and is configured such that the purge gas is supplied to a bottom of a deep groove formed in the wafer 200.

The exhauster 365 is configured to be able to exhaust gas independently of the exhauster 340. The exhauster 365 is also referred to as an auxiliary exhauster. As illustrated in FIG. 14, the exhauster 365 includes an exhaust pipe 365a communicating with the exhaust port 362. To the exhaust pipe 365a, a vacuum pump 365b as a vacuum exhaust device is connected via a valve 365d as an on-off valve and an APC valve 365c as a pressure regulator, which is configured to exhaust a purge gas supplied to the area 3.

The exhauster 365 may have higher exhaust performance than the exhauster 340. In this case, for example, the opening degree of the valve 365d is higher than that of the valve 344 of the exhauster 340, or performance of an exhaust pump of the exhauster 365 is higher than that of the exhauster 340.

The exhaust pipe 365a, the valve 365d, and the APC valve 365c are collectively referred to as the second exhauster 365. Note that the vacuum pump 365b may be included in the exhauster 365.

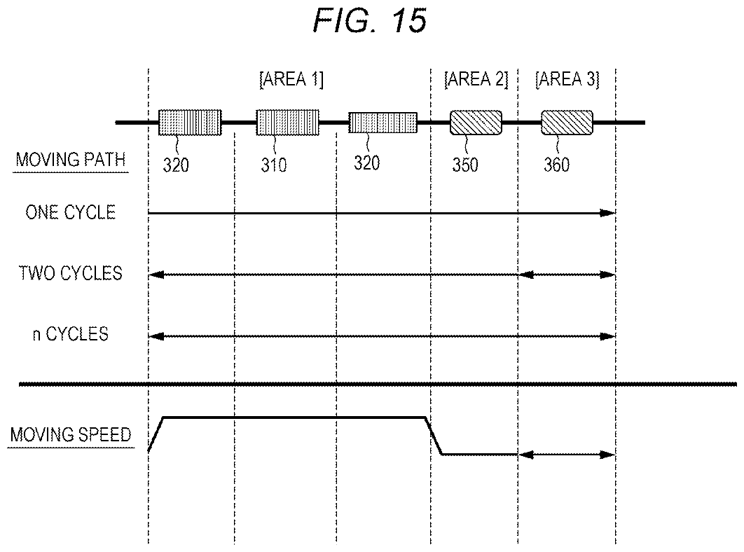

Subsequently, with reference to FIG. 15, the substrate processing step S103 will be described. In the area 1, a raw material gas is supplied from the raw material gas flow controller 310, and a reactant gas is supplied from the reactant gas flow controller 320 to form a desired layer on the wafer 200. For example, a titanium nitride (TiN) layer is formed using a TiCl₄ gas as the raw material gas and an NH₃ gas as the reactant gas.

A surface of the wafer 200 is exposed to various gases in the following order. The TiN layer formed in the area 1 is subjected to, for example, lamp heating in the area 3. By heating, an adhesive force of an excess component remaining on the surface of the wafer 200 and a by-product can be weakened. Examples of the by-product include ammonium chloride (NH₄Cl).

Next, in the area 3, a purge gas is supplied to the surface of the wafer 200, and the exhauster 365 is operated in parallel therewith to exhaust the atmosphere in the area 3. Specifically, by supplying the purge gas to the surface of the wafer 200, particularly to a bottom of a deep groove, the excess component and the by-product with a weakened adhesive force are desorbed from the inside of the deep groove of the wafer 200. Furthermore, since the atmosphere in the area 3 is exhausted by the exhauster 365, the excess component and the by-product are exhausted from the area 3, and re-adhesion to the wafer 200 is suppressed. This makes it possible to form a high-quality layer with less excess component and by-product.

Next, a moving path focusing only on the raw material gas, the reactant gas, the lamp, and the purge will be described.

Alternate supply of NH₃ and HCDS (area 1)→lamp heating (area 2)→purge (area 3)

By performing the above processing a plurality of times, a high-quality film with less excess component and by-product can be formed.

In addition, when lamp heating is performed in the area 2, the moving speed of the substrate mounting table 210 may be reduced to increase lamp irradiation time. As a result, the adhesive force of the excess component and the by-product can be weakened more reliably, and the excess component and the by-product can be easily desorbed.

In addition, when the excess component and the by-product are purged in the area 3, the substrate mounting table 210 may be swung to further weaken the adhesive force of the excess component and the by-product. As a result, the adhesive force of the excess component and the by-product can be weakened more reliably, and the excess component and the by-product can be easily desorbed.

In addition, here, processing is performed in the area 2 or 3 at all times after processing in the area 1, but this present disclosure is not limited thereto. The modification processing may be performed in the area 2 or 3 after processing is reciprocatedly performed a plurality of times in the area 1 depending on a required film quality.

In addition, it has been described here that the adhesion of the excess component and the by-product is weakened at all times in the area 2 after processing in the area 1, but the present disclosure is not limited thereto. The excess component and the by-product may be removed in the area 3 without performing processing in the area 2 depending on a required film quality.

According to the embodiment described above, a moving range in an area having the modifier can be reduced as compared with a case of performing a linear motion. Therefore, the volume of the processing container 101 can be reduced, and this makes it possible to perform different processing in the processing container.

### Other Embodiments

The first to third embodiments of this present disclosure have been specifically described above, but this present disclosure is not limited to the above-described embodiments, and various modifications can be made without departing from the gist of this present disclosure.

In the above embodiments, the processing of performing one cycle processing in the area 1 and then moving the substrate mounting table 210 to the area 2 or 3 to perform modification has been described, but this present disclosure is not limited thereto. The substrate mounting table 210 may be moved to the area 2 or 3 after being reciprocated in the area 1 to perform processing.

In the above embodiments, it has been described that the moving speed of the substrate mounting table 210 is reduced in the areas 2 and 3, but this present disclosure is not limited thereto. Operation of stopping the substrate mounting table 210 may be included. That is, when the substrate mounting table 210 reaches the area 2, the substrate mounting table 210 may be in a stopped state. In this case, the wafer 200 is processed in the stopped state.

In the above embodiments, two modification processing areas have been described as an example, but this present disclosure is not limited thereto. Three or more areas may be configured depending on the type of modification processing as long as being within a limited range of footprint.

For example, in each of the above-described embodiments, the example of forming the SiN film or the TiN film on the wafer 200 has been described. However, in addition thereto, this present disclosure can also be applied to, for example, a case of forming a conductive metal element-containing film (metal nitride film) such as a WN film, an insulating metal element-containing film (metal oxide film, high dielectric constant insulating film) such as a TiO film, an AlO film, an HfO film, or a ZrO film, an insulating half metal element-containing film (silicon insulating film) such as a SiO film, or the like.

In addition to the case of forming these binary films, this present disclosure can also be applied to a case of forming a ternary film or a quaternary film.

In addition, in each of the above-described embodiments, the film formation processing has been exemplified as the processing performed on the wafer, but this present disclosure is not limited thereto. This present disclosure can be applied even to other types of processing such as oxidation, nitridation, diffusion, annealing, etching, pre-cleaning, and chamber cleaning.

This present disclosure can provide a configuration capable of suppressing an increase in footprint of a substrate processing apparatus and coping with a plurality of types of processing having different processing times.

What is claimed is:

1. A substrate processing apparatus comprising:
a processing chamber having a film formation processing area and a modification processing area adjacent to the film formation processing area;
a film former configured to perform film formation processing on a substrate in the film formation processing area;
a modifier configured to perform modification processing different from the film formation processing on the substrate in the modification processing area;
a substrate mounter configured to support the substrate; and
a controller configured to be capable of controlling the substrate mounter such that a speed of moving the substrate is different between the film formation processing area and the modification processing area when the substrate moves in each of the film formation processing area and the modification processing area.

2. The substrate processing apparatus according to claim 1, wherein the controller controls the substrate mounter to stop in the modification processing area.

3. The substrate processing apparatus according to claim 1, wherein
the modification processing area includes a plurality of modification processing areas, and
the substrate mounter moves the substrate between the plurality of modification processing areas and the film formation processing area.

4. The substrate processing apparatus according to claim 3, wherein processing different from the film formation processing is performed in the plurality of modification processing areas.

5. The substrate processing apparatus according to claim 3, wherein different types of processing are performed in the plurality of modification processing areas.

6. The substrate processing apparatus according to any one of claim 1, wherein
the film former includes a raw material gas flow controller and a reactant gas flow controller, and
the raw material gas flow controller and the reactant gas flow controller perform control to move the substrate mounter between a portion below the raw material gas flow controller and a portion below the reactant gas flow controller to form a film on the substrate, then move the substrate mounter to the modification processing area, and cause the modifier to modify the film.

7. The substrate processing apparatus according to any one of claim 1, wherein
an exhauster is disposed in the film formation processing area, and
an auxiliary exhauster different from the exhauster disposed in the film formation processing area is disposed in the modification processing area, and the modification processing is performed while the auxiliary exhauster is operated in the modification processing area.

8. The substrate processing apparatus according to claim 7, wherein the substrate mounter is swung in the modification processing area.

9. The substrate processing apparatus according to any one of claim 1, wherein a speed of moving the substrate in the modification processing area is lower than a speed of moving the substrate in the film formation processing area.

10. A method of manufacturing a semiconductor device, the method comprising:
loading a substrate into a processing chamber having a film formation processing area and a modification processing area adjacent to the film formation processing area, and mounting the substrate on a substrate mounting table disposed in the processing chamber;
moving the substrate mounting table to the film formation processing area and performing film formation processing on the substrate; and
moving the substrate mounting table to the modification processing area, and performing modification processing different from the film formation processing on the substrate in the modification processing area at a moving speed different from a moving speed of the substrate mounting table in the film formation processing.

11. A non-transitory computer-readable recording medium storing a program that causes, by a computer, a substrate processing apparatus to perform:
loading a substrate into a processing chamber having a film formation processing area and a modification processing area adjacent to the film formation processing area, and mounting the substrate on a substrate mounting table disposed in the processing chamber;
moving the substrate mounting table to the film formation processing area and performing film formation processing on the substrate; and
moving the substrate mounting table to the modification processing area, and performing modification processing different from the film formation processing on the substrate in the modification processing area at a moving speed different from a moving speed of the substrate mounting table in the film formation processing.
